(19) United States
(12) Patent Application Publication
(10) Pub. No.: US 2010/0124121 A1
(43) Pub. Date: May 20, 2010

(54) METHOD OF ERASING FLASH MEMORY DEVICE

(76) Inventor: Ji Hyun SEO, Gyeonggi-do (KR)

Correspondence Address: IP & T Law Firm PLC, 7700 Little River Turnpike, Suite 207, Annandale, VA, 22003, US

(21) Appl. No.: 12/613,195

(22) Filed: Nov. 5, 2009

(30) Foreign Application Priority Data
Nov. 20, 2008 (KR) 10-2008-0115710

(51) Int. Cl. G11C 16/16; G11C 16/34

(52) U.S. Cl. 365/185.19; 365/185.33; 365/185.24; 365/185.22

(57) ABSTRACT

In a method of erasing a flash memory device according to an aspect of this disclosure, an erase operation is performed to lower threshold voltages of memory cells to a voltage level less than a first voltage. A first soft program operation is performed until a threshold voltage of any one of the memory cells reaches a second voltage higher than the first voltage. A second soft program operation is performed until a threshold voltage of any one of the memory cells reaches a third voltage higher than the second voltage.

### CROSS-REFERENCE TO RELATED APPLICATION

Priority to Korean patent application number 10-2008-0115710 filed on Nov. 20, 2008, the entire disclosure of which is incorporated by reference herein, is claimed.

### BACKGROUND

An embodiment relates to a method of erasing a flash memory device and, more particularly, to a method of erasing a flash memory device, which is capable of improving operating characteristics of a flash memory device.

A memory cell of a flash memory device becomes an erase state or a program state according to the level of a threshold voltage of the memory cell. To perform a program operation, all the memory cells of a memory cell block must maintain an erase state. It can be said that the program operation is an operation to raise the threshold voltages of the memory cells (i.e., the erase state) such that the threshold voltages reach a program level. Accordingly, the speed of a program operation may vary according to the level of a threshold voltage of the erased memory cell. This is described in more detail below.

FIG. 1 is a diagram illustrating known erase and program operations.

During the erase operation, an erase voltage (e.g., 20 V) is applied to the well of a memory cell block. The erase operation causes the threshold voltages of all memory cells of the memory cell block to be less than a reference voltage. The reference voltage is chiefly 0 V.

After the erase operation, it is ideal that all the cells have the same threshold voltage, but actually they do not have the same threshold voltage. That is, the threshold voltages of cells on which an erase operation has been performed can have a distribution, such as that indicated by a curve ‘a’ of FIG. 1. If the cells having the threshold voltage distribution indicated by the curve ‘a’ are programmed, the cells have a threshold voltage distribution indicated by a curve ‘b’. In slow cells having a relatively lower threshold voltage than other cells after an erase operation, the time that it takes to perform a program operation for the slow cells is longer than that for other cells. Accordingly, the time taken for a program operation to be executed is long.

### BRIEF SUMMARY

An embodiment relates to the improvement of a threshold voltage distribution of memory cells after an erase operation.

In a method of erasing a flash memory device according to an aspect, an erase operation is performed such that threshold voltages of memory cells become less than a first voltage. A first soft program operation is performed until a threshold voltage of any one of the memory cells reaches a second voltage higher than the first voltage. A second soft program operation is performed until a threshold voltage of any one of the memory cells reaches a third voltage higher than the second voltage.

The erase operation is performed using an incremental step pulse erase (ISPE) method.

The erase operation using the ISPE method comprises an erase step, an erase verification step, and an erase voltage rise step.

The erase verification step is performed using the first voltage as a reference voltage, and the first voltage has a voltage level less than 0 V.

The first soft program operation is performed using an incremental step pulse program (ISPP) method.

The first soft program operation using the ISPP method comprises a soft program step, a soft program verification step, and a soft program voltage rise step.

The soft program verification step of the first soft program operation is performed using the second voltage as a reference voltage, and the second voltage has a voltage level which is higher than the first voltage and less than 0 V.

The second soft program operation is performed using an ISPP method.

The second soft program operation using the ISPP method comprises a soft program step, a soft program verification step, and a soft program voltage rise step.

The soft program verification step of the second soft program operation is performed using the third voltage as a reference voltage, and the third voltage has a voltage level which is higher than the second voltage and less than 0 V.

In a method of erasing a flash memory device according to another aspect, an erase operation is performed such that threshold voltages of memory cells become less than a first voltage. A first soft program operation of an ISPP method using a first step voltage as a step pulse is performed until a threshold voltage of any one of the memory cells reaches a second voltage higher than the first voltage. A second soft program operation of an ISPP method using a second step voltage less than the first step voltage as a step pulse is performed until a threshold voltage of any one of the memory cells reaches a third voltage higher than the second voltage.

The third voltage is less than 0 V. Each of the first and second voltages is set in a range of 50 mV to 200 mV.

### BRIEF DESCRIPTION OF THE DRAWINGS

FIG. 1 is a diagram illustrating known erase and program operations;

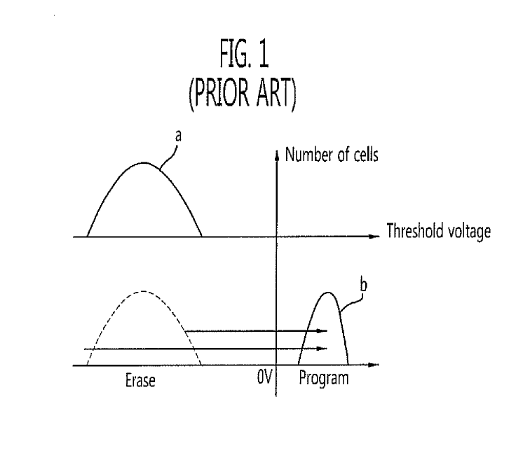

FIG. 2 is a flowchart illustrating a method of erasing a memory device according to an embodiment;

FIG. 3 is a diagram illustrating a shift in the distribution of threshold voltages for erasure according to a method of erasing a memory device of an embodiment of the present disclosure; and

FIGS. 4A to 4C are diagrams illustrating a verification operation of the erase operation according to this disclosure.

### DESCRIPTION OF EMBODIMENTS

Hereinafter, an embodiment of the present disclosure will be described in detail with reference to the accompanying drawings. The drawing figures are provided to allow those having ordinary skill in the art to understand the scope of the embodiment of the disclosure.

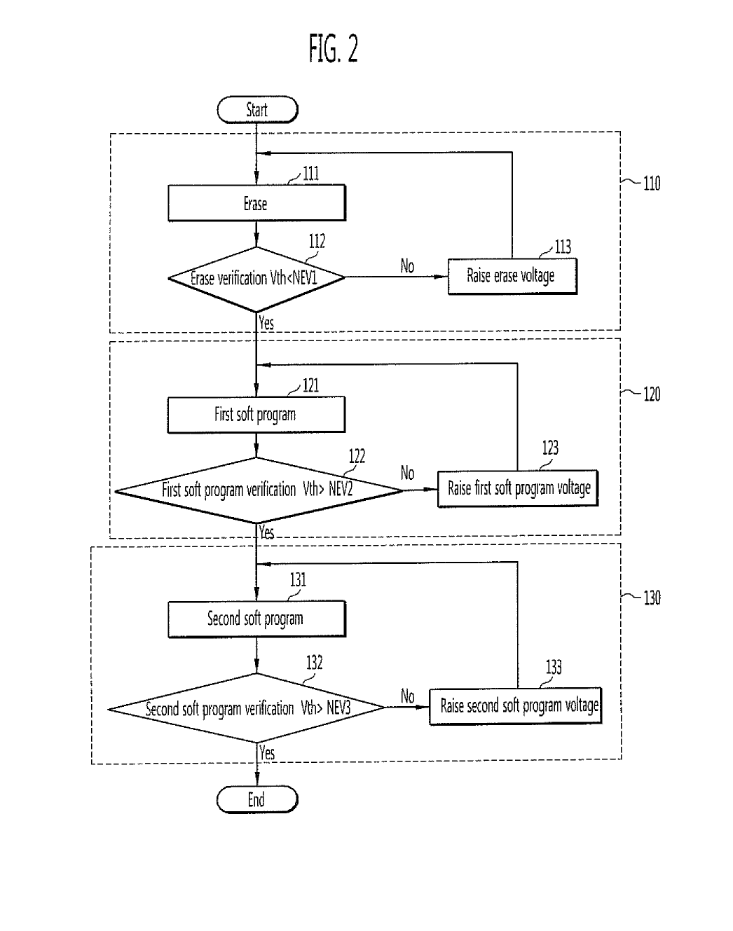

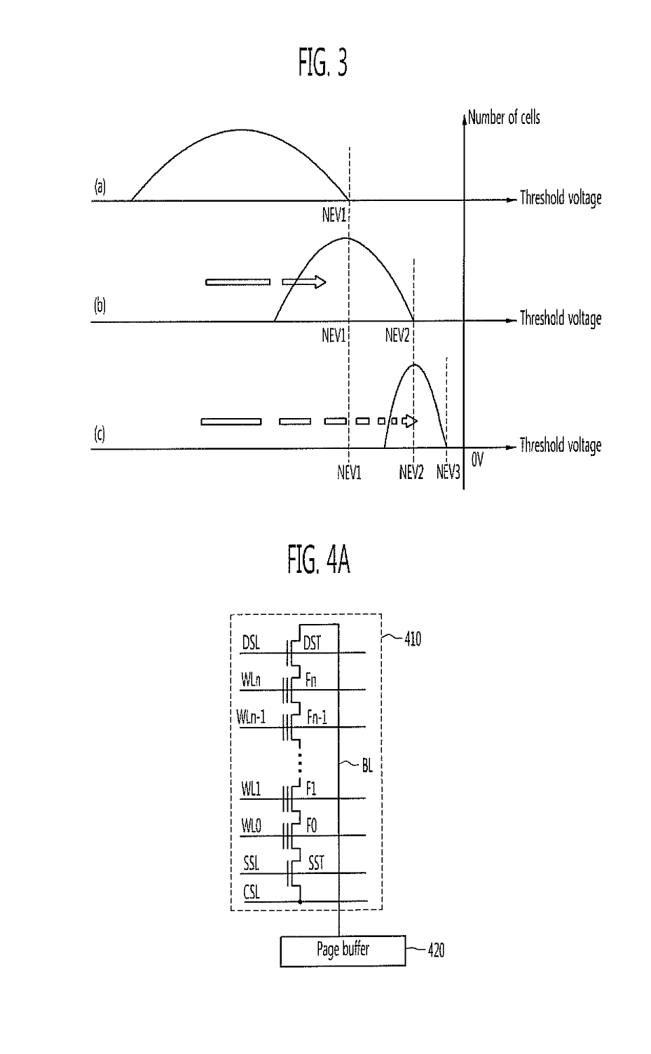

FIG. 2 is a flowchart illustrating a method of erasing a memory device according to an embodiment, and FIG. 3 is a diagram illustrating a shift in the distribution of threshold voltages for erasure according to a method of erasing a memory device.

Referring to FIG. 2, an erase operation is performed on all memory cells included in a memory cell block such that the threshold voltages of the memory cells are less than a ground voltage (0 V) (step 110). After the erase operation is performed, a first soft program operation (step 120) to raise the threshold voltages of the memory cells is performed, and a second soft program operation (step 130) to improve a threshold voltage distribution of the memory cells on which the first soft program operation (step 120) has been performed is performed.

Each of the operations is described in more detail below.

The erase operation is performed on all the memory cells within the memory cell block at step 111. The erase operation can be performed using a method of applying a single erase voltage to the well of a selected block or an ISPE method of gradually increasing the level of an erase voltage. The erase operation preferably is performed using the ISPE method.

After the erase operation (step 111), an erase verification operation is performed at step 112. The erase verification operation is performed to verify whether the threshold voltage (Vth) of each of the memory cells on which the erase operation has been performed is less than a first voltage (NEV1). If, as a result of the verification, there is any cell having the threshold voltage (Vth) higher than the first voltage (NEV1), the erase voltage is raised by a constant step (step 113), and the erase operation (step 111) is then performed again. However, if, as a result of the verification, the threshold voltages of all the memory cells are less than the first voltage (NEV1), the first soft program operation (step 120) is performed. Here, the first voltage (NEV1) is lower than 0 V.

Referring to (a) of FIG. 3, the threshold voltages of the memory cells become less than the first voltage (NEV1) by performing the erase operation as described above (step 110 of FIG. 2). At this time, a distribution of the threshold voltages is called a first distribution. The erase operation of step 110 is performed such that a maximum value of the threshold voltages is less than the first voltage (NEV1). Thus, the first distribution can be widened because the difference between a maximum value and a minimum value of the threshold voltages is further increased.

Referring to FIG. 2, if, as a result of the verification at step 112, there is no cell having the threshold voltage (Vth) higher than the first voltage (NEV1) (i.e., the erase operation is passed), then the first soft program operation to raise the threshold voltages of the memory cells is performed at step 120. The first soft program operation preferably is performed using an incremental step pulse program (ISPP) method. In the first soft program operation, the threshold voltages of the memory cells on which the erase operation has been performed are raised by applying a first soft program voltage to a corresponding word line. A verification operation after performing the first soft program operation (step 121) is performed at step 122. In the first soft program verification operation, a second voltage (NEV2) which is higher than the first voltage (NEV1), but less than 0 V is used as a reference voltage. In more detail, in the first soft program verification operation, if the threshold voltage (Vth) of each of all the memory cells is lower than the second voltage (NEV2), the first soft program voltage is raised, and the first soft program operation is performed again at step 123. Here, the amount of a change in the rising voltage is set to a first step voltage. The first step voltage can be set in the range of 50 mV to 200 mV. However, if there is any cell having the threshold voltage (Vth) higher than the second voltage (NEV2), the first soft program operation (step 120) is a pass.

Referring to (b) of FIG. 3, the threshold voltage of each of the memory cells can be raised by performing the first soft program operation (step 120 of FIG. 2), as described above, as compared with when the erase operation was performed. In this case, not only the level of the threshold voltage can be raised, but a distribution of the threshold voltages has a second distribution more improved than the first distribution.

Referring to FIG. 2, if, as a result of the verification operation at step 122, the first soft program operation (step 120) is a pass, then the second soft program operation (step 130) to narrow the distribution of the threshold voltages of the memory cells is performed. The second soft program operation preferably is performed using an ISPP method. In the second soft program operation, a second soft program voltage is applied to the corresponding word line. Thus, not only the threshold voltage of each of the memory cells on which the first soft program operation has been performed can be raised, but the distribution of the threshold voltages can be narrowed at step 131. A verification operation for the second soft program operation is performed at step 132. The second soft program verification operation is performed using a third voltage (NEV3), which is higher than the second voltage (NEV2), but less than 0 V, as a reference voltage. In more detail, in the second soft program verification operation, if the threshold voltage (Vth) of each of all the memory cells is lower than the third voltage (NEV3), the second soft program voltage is raised, and the second soft program operation is performed again at step 133. Here, the amount of a change in the rising voltage can be set to a second step voltage which is lower than the first step voltage, and the second step voltage can be set in the range of 50 mV to 200 mV. The reason why the amount of a change in the rising voltage is set to a second step voltage, which is lower than the first step voltage, is that a distribution of the threshold voltages can be further narrowed by lowering the first step voltage of the second soft program operation. However, if, as a result of the verification operation at step 132, there is any cell having the threshold voltage (Vth) higher than the third voltage (NEV3), the second soft program operation (step 130) is a pass, and so the method for erasing a memory device is completed.

Referring to (c) of FIG. 3, the threshold voltage of each of the memory cells can be raised, as compared to when the erase operation was performed, by performing the second soft program operation as described above (step 130 of FIG. 2). In this case, not only the level of the threshold voltage can be raised, but a distribution of the threshold voltages can have a third distribution narrower than the second distribution.

In the above operations, the use of the voltage as the reference voltage is described in more detail below.

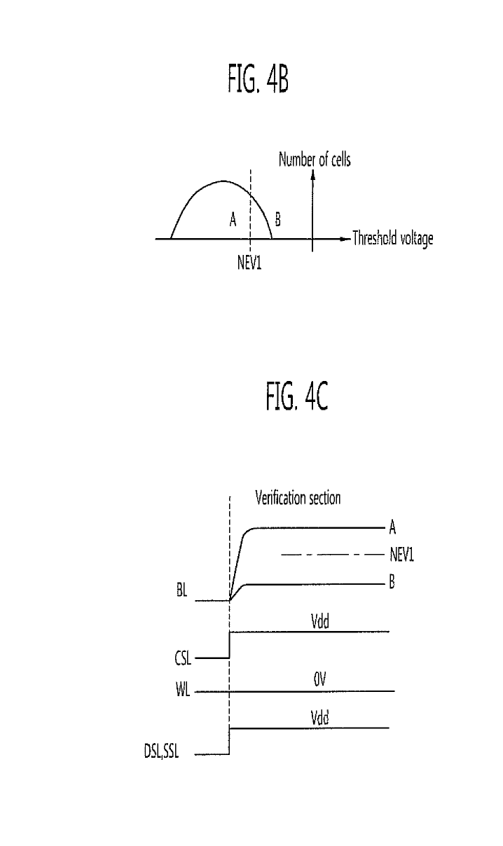

FIGS. 4A to 4C are diagrams illustrating the verification operation of the erase operation according to this disclosure.

The verification operation of the erase operation is performed using a negative voltage as a reference voltage. The verification operation can be performed by applying the negative voltage to a word line. In the case where the negative voltage cannot be applied to the word line, the verification operation is performed using the following method. An example in which the first voltage (NEV1) is used as the reference voltage is described below.

FIG. 4A is a circuit diagram schematically showing part of a flash memory device. The flash memory device includes a memory cell array unit 410 configured to store data and a page buffer 420 configured to controlling the 10 operation of data. The memory cell array unit 410 includes a plurality of strings each including memory cells. Only one string is shown for convenience of description. Each of the strings is electrically coupled to the page buffer 420 via a bit line BL.

In more detail, the string includes a number of the memory cells F0 to Fn coupled in series to each other, and a drain select transistor DST and a source select transistor SST coupled to opposite ends of the memory cells F0 to Fn. The bit line BL is coupled to the drain terminal of the drain select transistor DST, and a common source line CSL is electrically coupled to the source terminal of the source select transistor SST. The memory cells F0 to Fn included in different strings are coupled together to form a number of word lines WL0 to WLn. The drain select transistors DST included in different strings are coupled together to form the drain select line DSL. The source select transistors SST included in different strings are coupled together to form a source select line SSL.

Referring to FIGS. 4A to 4C, when an erase operation is performed, the threshold voltage of each of the memory cells on which the erase operation has been performed is lowered to have a negative voltage level less than 0 V (refer to FIG. 4B). In this case, in a verification section, a power source voltage (Vdd) is applied to the common source line CSL, a ground voltage (e.g., 0 V) is applied to all the word lines WL, and a turn-on voltage (e.g., a power source voltage) is applied to the drain select line DSL and the source select line SSL. Here, since the voltage applied to the word lines WL is more than the threshold voltage of each of the memory cells, channels are formed on the lower portions of the memory cells. Further, since the drain and source select transistors DST and SST are turned on by the voltage applied to the drain and source select lines DSL and SSL, the power source voltage (Vdd) applied to the common source line CSL is transferred to the bit line BL, thereby percharging the bit line BL.

In particular, there occurs a difference in the precharged voltage level of the bit line BL because a channel varies according to the level of the threshold voltage of the memory cell on which the erase operation has been performed. That is, with the level of the threshold voltage of a memory cell decreasing, the amount of current flowing through the channel is increased, and so the precharge voltage level of the bit line BL is increased (A). Furthermore, with the level of the threshold voltage of the memory cell increasing, the amount of current flowing through the channel is decreased, and so the precharge voltage level of the bit line BL is decreased (B). In particular, if, from among the memory cells on which the erase operation has been performed, there is any one memory cell having a threshold voltage higher than that of other memory cells, a precharged voltage level of the bit line BL is decreased.

As described above, there is a difference in the precharged voltage level of the bit line BL according to the threshold voltages of the memory cells on which the erase operation has been performed (refer to A and B). Thus, the page buffer 420 can determine whether the erase operation is a pass or a fail based on a positive voltage corresponding to an absolute value of the first voltage (NEV1). In other words, if a voltage level precharged to the bit line BL is higher than the first voltage (NEV1), the page buffer 420 determines that the erase operation has been completed. If a voltage level precharged to the bit line BL is less than the first voltage (NEV1), the page buffer 420 determines that the erase operation has not been completed.

As described above, since the soft program operations are performed after the erase operation is performed, a threshold voltage distribution of an erase state can be narrowed. Accordingly, the speed of a subsequent program operation can be increased.

Furthermore, a threshold voltage distribution of cells on which an erase operation has been performed can be improved, and so the speed of a program operation can be increased.

What is claimed is:

1. A method of erasing a flash memory device, comprising:
performing an erase operation such that threshold voltages of memory cells become less than a first voltage;
performing a first soft program operation until a threshold voltage of any one of the memory cells reaches a second voltage higher than the first voltage; and
performing a second soft program operation until a threshold voltage of any one of the memory cells reaches a third voltage higher than the second voltage.

2. The method of claim 1, wherein the erase operation is performed using an incremental step pulse erase (ISPE) method.

3. The method of claim 2, wherein the erase operation using the ISPE method comprises an erase step, an erase verification step, and an erase voltage rise step.

4. The method of claim 3, wherein the erase verification step is performed using the first voltage as a reference voltage.

5. The method of claim 1, wherein a voltage level of the first voltage is less than 0 V.

6. The method of claim 1, wherein the first soft program operation is performed using an incremental step pulse program (ISPP) method.

7. The method of claim 6, wherein the first soft program operation using the ISPP method comprises a soft program step, a soft program verification step, and a soft program voltage rise step.

8. The method of claim 7, wherein the soft program verification step is performed using the second voltage as a reference voltage.

9. The method of claim 1, wherein a voltage level of the second voltage is higher than the first voltage.

10. The method of claim 9, wherein the second voltage is less than 0V.

11. The method of claim 1, wherein the second soft program operation is performed using an ISPP method.

12. The method of claim 11, wherein the second soft program operation using the ISPP method comprises a soft program step, a soft program verification step, and a soft program voltage rise step.

13. The method of claim 11, wherein the soft program verification step is performed using the third voltage as a reference voltage.

14. The method of claim 1, wherein a voltage level of the third voltage is higher than the second voltage.

15. The method of claim 14, wherein the third voltage is less than 0V.

16. A method of erasing a flash memory device, comprising:
performing an erase operation such that threshold voltages of memory cells become less than a first voltage;
performing a first soft program operation of an Incremental Step Pulse Program (ISPP) method using a first step voltage as a step pulse until a threshold voltage of any one of the memory cells reaches a second voltage which is higher than the first voltage; and
performing a second soft program operation of an Incremental Step Pulse Program (ISPP) method using a second step voltage less than the first step voltage as a step pulse until a threshold voltage of any one of the memory cells reaches a third voltage which is higher than the second voltage.

17. The method of claim 16, wherein the first voltage is less than 0 V.

18. The method of claim 16, wherein each of the first and second voltages is set in a range of 50 mV to 200 mV.

19. The method of claim 16, wherein the second voltage is less than 0V.

20. The method of claim 16, wherein the third voltage is less than 0V.
